(19) United States
(12) Patent Application Publication
(10) Pub. No.: US 2018/0166353 A1
(43) Pub. Date: Jun. 14, 2018

(54) GLASS SUBSTRATE ASSEMBLIES HAVING LOW DIELECTRIC PROPERTIES

(71) Applicant: Corning Incorporated, Corning, NY (US)

(72) Inventors: Sean Matthew Garner, Elmira, NY (US); Jen-Chieh Lin, Zhubei (TW); Michael Lesley Sorensen, Waverly, NY (US)

(21) Appl. No.: 15/753,889

(22) PCT Filed: Aug. 19, 2016
(86) PCT No.: PCT/US2016/047728

§ 371 Date: Feb. 20, 2018

Related U.S. Application Data
(60) Provisional application No. 62/208,282, filed on Aug. 21, 2015.
(60) Provisional application No. 62/232,076, filed on Sep. 24, 2015.

(51) Int. Cl. H01L 23/15; C03B 33/02; C03C 17/00; C03C 23/00; H01L 21/48; H05K 1/02; H05K 1/03

(52) U.S. Cl. CPC H01L 23/15; C03B 33/0222; C03C 17/008; C03C 23/007; H01L 21/4807; H05K 1/024; H05K 3/107; C03C 2217/445; H05K 1/036; H05K 2201/0195; H05K 2203/1194; H05K 2203/1545; H05K 1/0306

(57) ABSTRACT

Glass substrate assemblies having low dielectric properties, electronic assemblies incorporating glass substrate assemblies, and methods of fabricating glass substrate assemblies are disclosed. In one embodiment, a substrate assembly includes a glass layer 110 having a first surface and a second surface, and a thickness of less than about 300 μm. The substrate assembly further includes a dielectric layer 120 disposed on at least one of the first surface or the second surface of the glass layer. The dielectric layer has a dielectric constant value of less than about 3.0 in response to electromagnetic radiation having a frequency of 10 GHz. In some embodiments, the glass layer is made of annealed glass such that the glass layer has a dielectric constant value of less than about 5.0 and a dissipation factor value of less than about 0.003 in response to electromagnetic radiation having a frequency of 10 GHz. An electrically conductive layer 142 is disposed on a surface of the dielectric layer, within the dielectric layer or under the dielectric layer.

This application claims the benefit of priority to U.S. Provisional Application Nos. 62/208,282, filed Aug. 21, 2015, and 62/232,076, filed Sep. 24, 2015, the content of each of which is incorporated herein by reference in its entirety.

### BACKGROUND

### Field

The present specification generally relates to substrates for electronics applications and, more particularly, to glass substrate assemblies having low dielectric properties in response to high frequency electronic signals.

### Technical Background

With advances in electronic technologies, more high frequency devices are needed in the areas of wireless communications, satellite communications and high speed data transfer applications. However, there are concerns regarding electrical losses due to the dielectric properties of flexible printed circuit boards (FPC) or printed circuit boards (PCB) in high speed applications (e.g., 10 GHz or higher). Current FPC substrates, such as polymer or polymer/glass fiber composite, may not be qualified for future device applications at high frequency. Therefore, low dielectric constant (e.g., less than about 3.0) and low dissipation factor (e.g., less than about 0.003) substrates may be needed. Although some thin glass substrates may meet desired dissipation factor goals, the dielectric constant of such glass substrates may be too high in some high frequency applications.

Accordingly, there exists a need for substrates having low dielectric constant and dissipation factor properties in response to high frequency electronic signals.

### SUMMARY

In one embodiment, a substrate assembly includes a glass layer having a first surface and a second surface. The substrate assembly further includes a dielectric layer disposed on at least one of the first surface or the second surface of the glass layer. The dielectric layer has a dielectric constant value of less than about 3.0 in response to electromagnetic radiation having a frequency of 10 GHz.

In another embodiment, an electronic assembly includes a glass layer including a first surface and a second surface, a dielectric layer disposed on at least one of the first surface or the second surface of the glass layer, a plurality of electrically conductive traces positioned within the dielectric layer, under the dielectric layer, or on a surface of the dielectric layer, and an integrated circuit component disposed on the surface of the dielectric layer and electrically coupled to one or more electrically conductive traces of the plurality of electrically conductive traces. The dielectric layer has a dielectric constant value of less than about 3.0 in response to electromagnetic radiation having a frequency of 10 GHz, and the integrated circuit component is configured to perform at least one of transmitting or receiving wireless communication signals.

In yet another embodiment, a method of fabricating a glass substrate assembly includes heating a glass substrate to a first temperature that is greater than a strain point of the glass substrate and less than a softening point of the glass substrate, and maintaining the glass substrate within about 10% of the first temperature for a first period of time. The method further includes cooling the glass substrate to a second temperature over a second period of time such that, following cooling the glass substrate, the glass substrate has a dielectric constant value of less than about 5.0 in response to electromagnetic radiation having a frequency of 10 GHz. A dielectric layer is applied to at least one surface of the glass substrate, wherein the dielectric layer has a dielectric constant value of less than about 2.5 in response to electromagnetic radiation having a frequency of 10 GHz.

### BRIEF DESCRIPTION OF THE DRAWINGS

The foregoing will be apparent from the following more particular description of the example embodiments, as illustrated in the accompanying drawings in which like reference characters refer to the same parts throughout the different views. The drawings are not necessarily to scale, emphasis instead being placed upon illustrating the representative embodiments.

FIG. 1 schematically depicts a portion of an example glass substrate assembly comprising a dielectric layer coupled to a surface of a glass layer according to one or more embodiments described and illustrated herein;

FIG. 2 schematically depicts the dielectric layer being applied to the surface of the glass layer depicted in FIG. 1 according to one or more embodiments described and illustrated herein;

FIG. 3 schematically depicts an example roll-to-roll process to apply one or more dielectric layers to a glass layer according to one or more embodiments described and illustrated herein;

FIG. 4 schematically depicts an example slot-die process to apply one or more dielectric layers to a glass layer according to one or more embodiments described and illustrated herein;

FIG. 5 schematically depicts an example lamination process to apply one or more dielectric layers to a glass layer according to one or more embodiments described and illustrated herein;

FIG. 6A schematically depicts a side view of a glass substrate assembly including a glass layer, a dielectric layer, and an electrically conductive layer according to one or more embodiments described and illustrated herein;

FIG. 6B schematically depicts a partial perspective view of a glass substrate assembly including a glass layer, a dielectric layer, and an electrically conductive layer including at least one electrically conductive trace according to one or more embodiments described and illustrated herein;

FIG. 7A schematically depicts a partial perspective view of an example glass substrate assembly including a dielectric layer having a three dimensional feature configured as a channel according to one or more embodiments described and illustrated herein;

FIG. 7B schematically depicts a partial side view of an example glass substrate assembly having a glass layer, a dielectric layer, and a three dimensional feature configured as a channel in the dielectric layer according to one or more embodiments described and illustrated herein;

FIG. 8A schematically depicts a side view of an example glass substrate assembly including alternating glass layers and dielectric layers according to one or more embodiments described and illustrated herein;

FIG. 8B schematically depicts a cross-sectional view of a glass substrate assembly including alternating glass layers, dielectric layers, and electrically conductive layers, and electrically conductive vias that electrically couple electrically conductive layers, according to one or more embodiments described and illustrated herein;

FIG. 9 schematically depicts an electronic assembly including a glass substrate assembly according to one or more embodiments described and illustrated herein; and

FIG. 10 schematically depicts a glass substrate being annealed in a furnace according to one or more embodiments described and illustrated herein.

### DETAILED DESCRIPTION

The embodiments disclosed herein relate to glass substrate assemblies exhibiting desirable dielectric properties in response to high frequency electronic signals, such as signals defined by various wireless communication protocols. Particularly, the glass substrate assemblies described herein exhibit desirable dielectric constant and dissipation loss values in response to electronic signals having frequencies of 10 GHz and higher. Example glass substrates comprise a dielectric layer disposed on one or both surfaces of a thin glass layer.

As described in more detail below, the material of the dielectric layer is chosen to have a low dielectric constant value and a low dissipation loss value in response to electronic signals having a frequency of 10 GHz and higher. The dielectric properties of the dielectric layer lower the effective dielectric properties of the overall composite structure, thereby enabling the use of glass as a substrate in high speed electronic applications, such as high speed communication applications. The dielectric layer not only provides for desirable dielectric properties at high frequencies, but also adds mechanical protection to the glass surface.

Further, also disclosed herein are methods for lowering the dielectric constant value and dissipation loss value of the glass layer in response to high frequency electronic signals. Particularly, an annealing process is used in some embodiments to lower dielectric properties of the glass layer. The dielectric layer may then be disposed on one or more surfaces of the annealed glass layer.

Use of thin glass as a substrate for flexible circuit board applications may provide several advantages over traditional flexible printed circuit board materials, which are commonly made of polymers or polymer/glass fiber composites. These advantages include, but are not limited to, better thermal properties (including thermal capability as well as thermal conductivity), increased optical quality such as optical transmission, increased thickness control, better surface quality, better dimensional stability, and better hermeticity over traditional flexible printed circuit board materials. These properties may enable, without limitation: thermal excursions >300° C.; thermal conductivity >0.01 W/cm K; optically transparent or semi-transparent applications with transmission >50%, >70%, or >90%; electronic device structures with feature resolution <50 μm, <20 μm, <10 μm, or <5 μm; water vapor transmission rate <10⁻⁶ g/m²/day; multi-layer devices with layer-to-layer registration <10 μm, <5 μm, or <2 μm; or electronic frequency applications ≥10 GHz, ≥20 GHz, ≥50 GHz, or ≥100 GHz.

Various glass substrate assemblies, electronic assemblies, and methods of fabricating glass substrate assemblies are described in detail below.

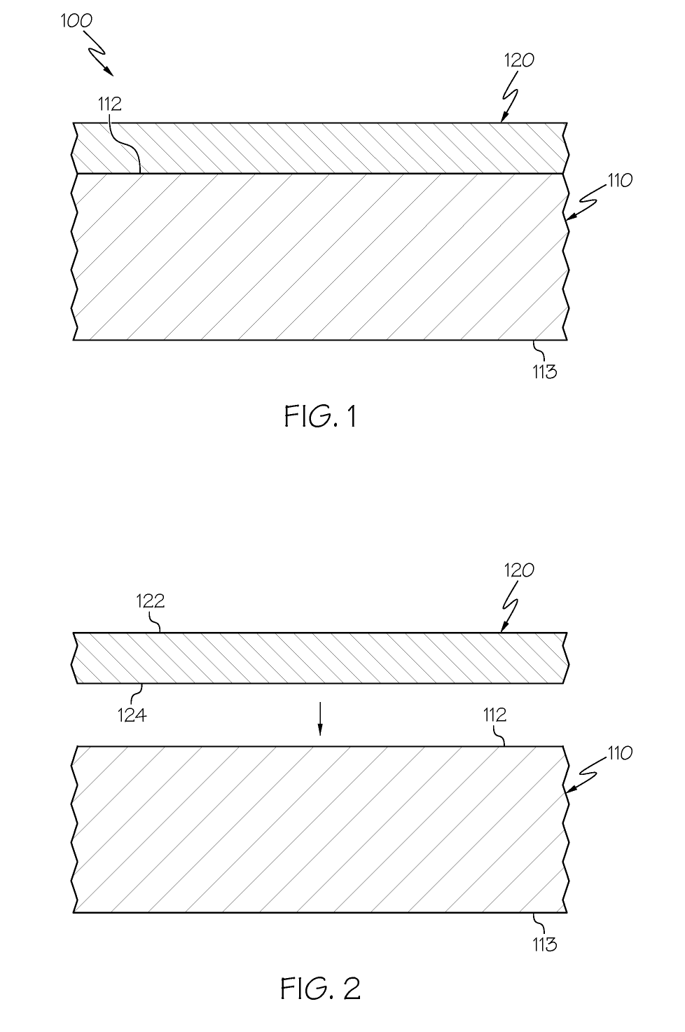

Referring now to FIGS. 1 and 2, a portion of an example glass substrate assembly 100 is schematically illustrated. The glass substrate assembly 100 of the illustrated embodiment includes a glass layer 110 fabricated from a glass substrate, and a dielectric layer 120 disposed on a first surface 112 of the glass layer 110. Although the glass substrate assembly 100 is illustrated in FIGS. 1 and 2 as only having a dielectric layer 120 disposed on the first surface 112 of the glass layer 110, it should be understood that another dielectric layer may be disposed on the second surface 113 of the glass layer 110 in other embodiments. Further, multiple dielectric layers of the same or different materials may be stacked on one another. As described in more detail below, the glass substrate assembly 100 may be utilized as a flexible printed circuit board in electronic applications, such as high speed wireless communication applications, for example.

In embodiments, the glass layer 110 has a thickness such that it is flexible. Example thicknesses include, but are not limited to, less than about 300 μm, less than about 200 μm, less than about 100 μm, less than about 50 μm, and less than about 25 μm. Additionally, or alternatively, example thicknesses include, but are not limited to, greater than about 10 μm, greater than about 25 μm, greater than about 50 μm, greater than about 75 μm, greater than about 100 μm, greater than about 125 μm, or greater than about 150 μm. An example of a glass substrate being flexible is the ability to bend it at a radius of below 300 mm, or a radius below 200 mm, or a radius below 100 mm. It is noted that, in high frequency wireless communication applications, the thinner the glass layer 110 the better so that the effective dielectric properties of the glass substrate assembly 100 are dominated more by the dielectric layer 120 than the glass layer 110. It should be understood that, in other embodiments, the glass layer 110 is not flexible, and may have a thickness greater than about 200 μm. In embodiments, the glass layer 110 comprises, consists essentially of, or consists of a glass material, a ceramic material, a glass-ceramic material, or combinations thereof. As non-limiting examples, the glass layer 110 may be a borosilicate glass (e.g., glass manufactured by Corning Incorporated of Corning, N.Y. under the trade name Willow® Glass), an alkaline Earth boro-aluminosilicate glass (e.g., glass manufactured by Corning Incorporated under the trade name EAGLE XG®), and an alkaline earth boro-aluminosilicate glass (e.g., glass manufactured by Corning Incorporated under the trade name Contego Glass). It should be understood that other glass, glass ceramic, ceramic, multi-layers, or composite compositions may also be utilized.

The dielectric layer 120 may be any material capable of being secured to one or more surfaces of the glass layer 110, and any material having a dielectric constant value and a dissipation factor value such that the effective dielectric constant value and the effective dissipation factor value of the glass substrate assembly 100 is less than or equal to 5.0 and less than or equal to 0.003 in response to electromagnetic radiation having a frequency of 10 GHz, respectively. It is noted that the phrase “electromagnetic radiation” and “electronic signals” are used interchangeably herein, and mean signals that are transmitted and received according to one or more wireless communication protocols or propagated along the electronic circuit fabricated on or within the glass substrate assembly 100. This includes electromagnetic radiation that is transmitted from one location to another location on the glass substrate assembly 100 along defined conductor paths, as well as electromagnetic radiation that is transmitted or received wirelessly to or from the ambient environment. Electronic conductor paths fabricated on or within the glass substrate assembly 100 can include stripline, micro-stripline, coplanar transmission line, and other combinations of electrical signal and ground conductors. Further, the terms “dielectric constant value” and “dissipation factor value” mean the dielectric constant and dissipation factor of the referenced specific intrinsic substrate layer or the specific intrinsic dielectric layer properties in response to 10 GHz using the split cylinder resonator method. The split cylinder method for measuring the complex permittivities of materials is known and equipment commercially available, and is described as IPC Standard TM-650 2.5.5.13. It should be understood that glass substrate assemblies 100 described herein may operate at frequencies greater than 10 GHz, and that 10 GHz was chosen only for benchmarking and quantitative purposes. As an example and not a limitation, the dielectric layer 120 may have a dielectric constant value of less than about 5.0 and a dissipation factor value of less than about 0.003 in response to electromagnetic radiation having a frequency of 10 GHz. As another non-limiting example, the dielectric layer 120 has a dielectric constant value within a range of about 2.2 to about 2.5 and a dissipation factor of less than about 0.0003 in response to electromagnetic radiation having a frequency of 10 GHz. The terms “effective dielectric constant value” and the “effective dissipation factor value” refer to the response of the electromagnetic propagation along the defined transmission line or conductor path on the glass substrate assembly 100. In this case, the electronic signal propagates on the transmission line or conductor path fabricated on the glass substrate assembly 100 with the same speed and loss as if it were embedded in a uniform material with an “effective dielectric constant value” and an “effective dissipation factor value”.

Example materials for the dielectric layer 120 include, but are not limited to, inorganic materials such as silica and low dielectric constant (low-k) polymer materials. Example low-k polymer materials include, but are not limited to, polyimide, aromatic polymers, parylene, aramid, polyester, Teflon®, and polytetrafluoroethylene. Additional low-k materials include oxide xerogels and aerogels. Other materials are also possible including porous structures. It should be noted that any material with a dielectric constant of less than about 5.0 at a frequency of 10 GHz capable of being deposited on one or more surfaces of the glass layer 110 may be utilized.

Several example ultra-violet (“UV”) curable dielectric coatings were evaluated for dielectric constant value (Dk) and dissipation loss factor value (DO at electromagnetic radiation frequencies of 2.986 GHz and 10 GHz. Table 1 below depicts Dk and Df for the example UV curable dielectric coatings evaluated at 2.986 GHz and 10 GHz using the split cylinder resonator method. Such materials may be suitable for the dielectric layer(s) 120 described herein.

TABLE 1
Dk and Df Values of Materials Tested at 2.986 GHz and 10 GHz

| | Frequency | |
|---|---|---|
| Dielectric Coating | 2.986 GHz | 10 GHz |

| Formulation Ref. No | Dk | Df | Dk | Df |
|---|---|---|---|---|
| 1 | 2.96 | 0.0208 | 2.31 | 0.0186 |
| 2 | 2.98 | 0.0194 | | |
| 3 | 2.88 | 0.0095 | 2.3 | 0.0088 |
| 4 | 3.48 | 0.04371 | | |
| 5 | 3.16 | 0.0266 | 2.5 | 0.0214 |
| 6 | 2.87 | 0.0065 | | |
| 7 | | | 2.2 | 0.0146 |
| 8 | 3.16 | 0.0087 | | |
| 9 | 2.9 | 0.0201 | | |
| 10 | 2.91 | 0.0078 | | |
| 11 | 2.93 | 0.0097 | | |
| 12 | 2.96 | 0.008 | | |
| 13 | 3.03 | 0.008 | | |
| 14 | | | 2.65 | 0.0144 |
| 15 | | | 2.85 | 0.0142 |

Each dielectric coating in Table 1 includes a Formulation Reference Number. The formulation of each dielectric coating is provided in Table 2A and Table 2B by reference to its Formulation Reference Number. The values disclosed in Table 2A and Table 2B are representative of the parts by weight of each material in the respective formulations. The dielectric coating formulations, in various embodiments, included one or more materials such as acrylate monomers chosen from isobornyl acrylate, dicyclopentyl acrylate, adamantyl methacrylate, phenoxy benzyl acrylate (commercially available as Miramer M1120 from Miwon Specialty Chemical Co. of South Korea), tricyclodecane dimethanol diacrylate (commercially available as SR833 S from Arkema S.A. of France), and/or dicyclopentadienyl methacrylate (commercially available as CD535 from Arkema S.A. of France); fluorinated acrylate materials chosen from bisphenol fluorene diacrylate (commercially available as Miramer HR6060 from Miwon Specialty Chemical Co. of South Korea) and/or perfluoropolyether (PFPE)-urethane acrylate (commercially available as Fluorolink® AD1700 from Solvay S.A. of Belgium); and photoinitiators chosen from 1-Hydroxy-cyclohexyl-phenyl-ketone (commercially available as Irgacure® 184 from BASF SE of Germany) and/or Bis(2,4,6-trimethylbenzoyl)-phenylphosphineoxide (commercially available as Irgacure® 819 from BASF SE of Germany).

TABLE 2A
Formulations of Dielectric Coating by Formulation Reference Number

| | Formulation | | | | | | | | | |
|---|---|---|---|---|---|---|---|---|---|---|
| Material | 1 | 2 | 3 | 4 | 5 | 6 | 7 | 8 | 9 | 10 |
| Isobornyl | 6 | 6 | 6 | 2 | 4 | 6 | — | 6 | 4 | 6 |
| Acrylate | | | | | | | | | | |
| Fluorolink ® | 2 | — | — | 2 | 2 | — | 2 | — | 2 | — |
| AD1700 | | | | | | | | | | |
| Miramer | — | 2 | — | 4 | — | — | — | — | — | — |
| HR6060 | | | | | | | | | | |
| SR833 S | — | — | 2 | — | 4 | — | — | — | — | |
| CD535 | — | — | — | — | — | 2 | 6 | | 2 | — |
| Miramer M1122 | — | — | — | — | — | — | — | 2 | — | — |
| Dicyclopentyl | — | — | — | — | — | — | — | — | — | 2 |
| Acrylate | | | | | | | | | | |
| Adamantyl | — | — | — | — | — | — | — | — | — | — |
| Methacrylate | | | | | | | | | | |
| Irgacure ® 184 | 0.04 | 0.04 | 0.04 | 0.04 | 0.04 | 0.04 | 0.04 | 0.04 | 0.04 | 0.04 |
| Irgacure ® 819 | 0.08 | 0.08 | 0.08 | 0.08 | 0.08 | 0.08 | 0.08 | 0.08 | 0.08 | 0.08 |

TABLE 2B
Formulations of Dielectric Coating by Formulation Reference Number

| | Formulation | | | | | |
|---|---|---|---|---|---|---|
| Material | 10 | 11 | 12 | 13 | 14 | 15 |
| Isobornyl | 6 | 2 | 4 | 2 | 6 | 6 |
| Acrylate | | | | | | |
| Fluorolink ® | — | 2^{†} | 2* | 2* | 2* | 2* |
| AD1700 | | | | | | |
| Miramer | — | — | — | — | — | — |
| HR6060 | | | | | | |
| SR833 S | — | — | — | 4 | — | — |
| CD535 | — | — | 2 | — | — | 4 |
| Miramer M1122 | — | — | — | — | — | — |
| Dicyclopentyl | 2 | 4 | — | — | — | — |
| Acrylate | | | | | | |
| Adamantyl | — | — | — | — | 4 | — |
| Methacrylate | | | | | | |
| Irgacure ® 184 | 0.04 | 0.04 | 0.04 | 0.04 | 0.04 | 0.04 |
| Irgacure ® 819 | 0.08 | 0.08 | 0.08 | 0.08 | 0.08 | 0.08 |

*Fluorolink ® AD1700 formulation made with AD1700 which had been solvent exchanged with IBOA, wherein the value in the cell represents the amount of AD1700 in the IBOA/AD1700 mixture
^{†}Fluorolink ® AD1700 formulation made with AD1700 from which the solvent had been removed.

It is noted that the amount of photoinitiator included in the formulations is suitable for coatings cured between glass. These levels may not yield samples with sufficient surface cure if they are cured with one surface exposed.

The dielectric layer(s) 120 may be applied to the surface(s) of the glass layer 110 by any suitable process. As the glass layer 110 may be a flexible material, the dielectric layer 120 may be applied to the glass layer 110 by a roll-to-roll process. The dielectric layer 120 may also be applied to individual sheets of glass rather than in a roll-to-roll process.

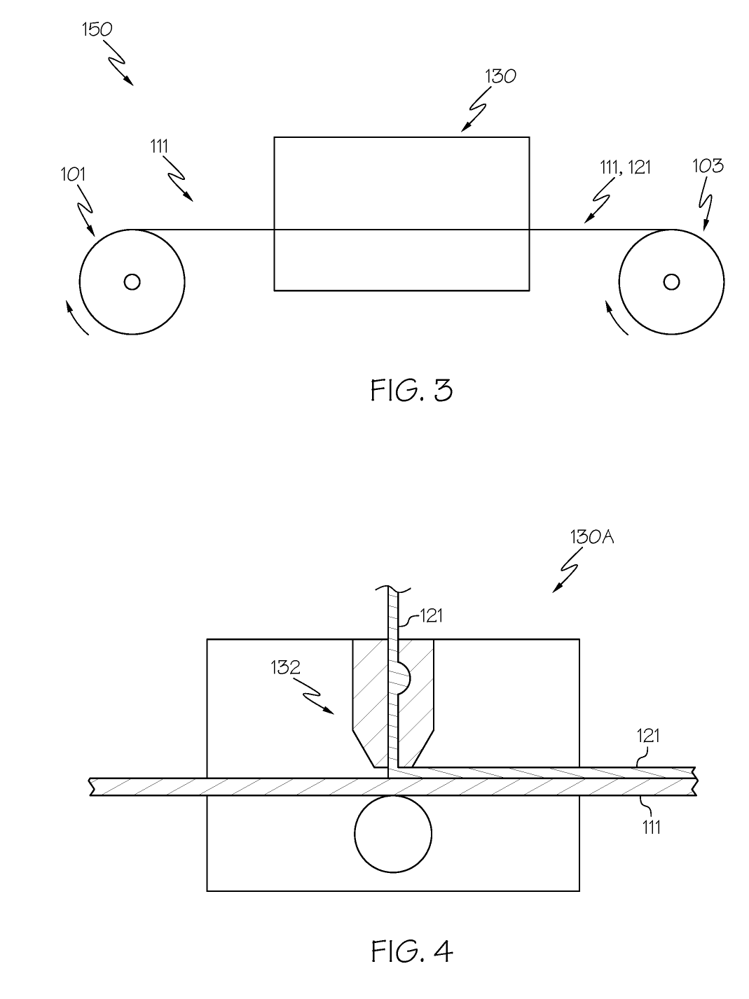

Referring now to FIG. 3, a roll-to-roll process 150 for depositing a dielectric material 121 onto a glass web 111 is schematically illustrated. It is noted that the dielectric material 121 and the glass web 111 form the dielectric layer 120 and the glass layer 110, respectively, when cut to size to form the glass substrate assembly 100. In the illustrated embodiment, the glass web 111 is in the form of an initial spool 101. The flexible glass web 111 may be wound around a core, for example. The glass web 111 is then unwound toward and through a dielectric layer depositing system 130. The dielectric layer depositing system 130 deposits the dielectric material 121 onto one or both surfaces of the glass web 111. After receiving the dielectric material 121, the glass web 111 may be wound into a second spool 103 in some embodiments. The coated glass web 111 of the second spool 103 may then be sent to one or more downstream processes, such as, without limitation, via formation (e.g., by laser drilling), electroplating (e.g., to form electrically conductive traces and planes), additional coating, dicing, and electrical component populating. Similarly, the glass web 111 (or glass sheets in a sheet process) may be subjected to one or more upstream processes before depositing a dielectric material 121. Similarly, these upstream processes could include, without limitation, via formation (e.g., by laser drilling), electroplating (e.g., to form electrically conductive traces and planes), additional coating, dicing, and electrical component populating. Also, if the dielectric material 121 is deposited onto both surfaces of the glass web 111 or glass sheets, it does not need to be symmetric. The dielectric material 121 composition, patterning, thicknesses, and other properties on one surface of the glass web 111 or glass sheet can vary from the dielectric material properties on the other surface of the glass web or substrate.

The dielectric layer depositing system 130 may be any assembly or system capable of depositing the dielectric material 121 onto the glass web 111. As an example and not a limitation, FIG. 4 schematically depicts an example slot-die coating system 130A utilized to deposit a dielectric material 121 onto a flexible glass web 111, such as in a roll-to-roll process. It should be understood that the dielectric material 121 may be coated onto both surfaces of the glass web 111, although only one surface is shown as coated in FIG. 1. The system 130A includes a slot-die that continuously deposits the dielectric material 121 onto a surface of the glass web 111. It should be understood that, in embodiments wherein both surfaces of the glass web 111 are coated with the dielectric material 121, another slot-die may be provided to coat the second surface. Further, additional processing assemblies or systems may also be provided that are not shown in FIG. 4, such as a curing assembly (e.g., thermal curing, UV curing, and the like). It should be understood that coating systems other than slot-die coating may be utilized. Such additional coating systems may include, without limitation, solution-based processes such as printing methods, or other coating methods. The coating system can also include inorganic thin film deposition techniques such as sputtering, PECVD, ALD, and other processes. These methods may be used to deposit continuous layers of dielectric material 121 onto the glass substrate. These methods can also be used to deposit patterned dielectric material layers that include areas of the glass substrate that are coated and non-coated or with regions of the dielectric material that include 3D shapes, vertical contours, or complex 3D contours such as varying thicknesses, channels, vias, ridges, or post structures.

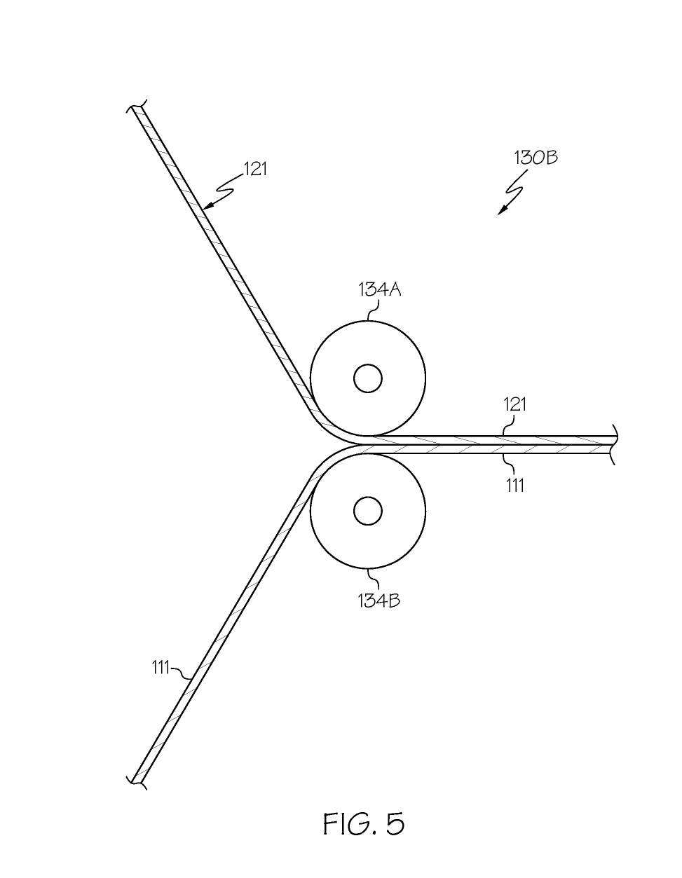

Referring now to FIG. 5, an example lamination system 130B for applying a dielectric material 121 to a flexible glass web 111 is schematically illustrated. The lamination system 130B includes at least two rollers 134A, 134B. The dielectric material 121 and the flexible glass web 111 are fed between the rollers 134A, 134B to laminate the dielectric material 121 to the flexible glass web 111. In some embodiments, the laminated flexible glass web 111 may then be rolled into a spool. Any known or yet-to-be-developed lamination process may be utilized.

As stated above, the dielectric material 121 may be applied to individual sheets of the glass substrate 111 rather than in a roll-to-roll process.

After application of the dielectric material 121 to the glass substrate or web 111, the coated glass substrate/web 111 may then be severed into a plurality of glass substrate assemblies having one or more desired shapes. The low dielectric constant value and dissipation factor value of glass substrate assembly 100 at relatively high frequencies of electromagnetic radiation make it ideal for use as a flexible printed circuit board in wireless communication applications.

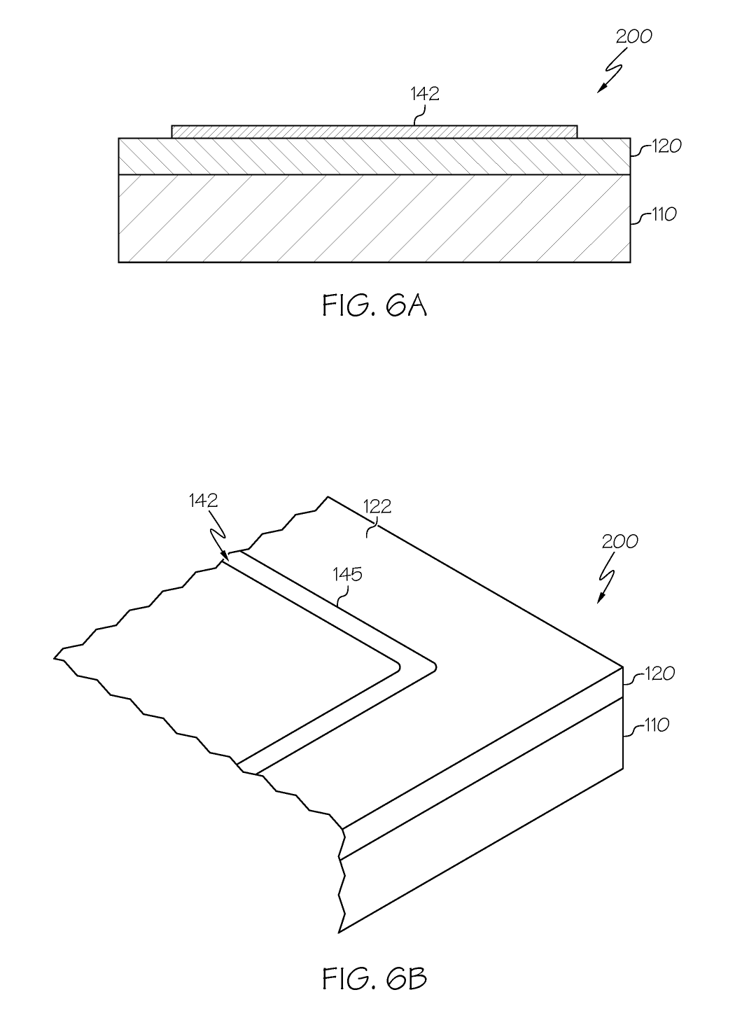

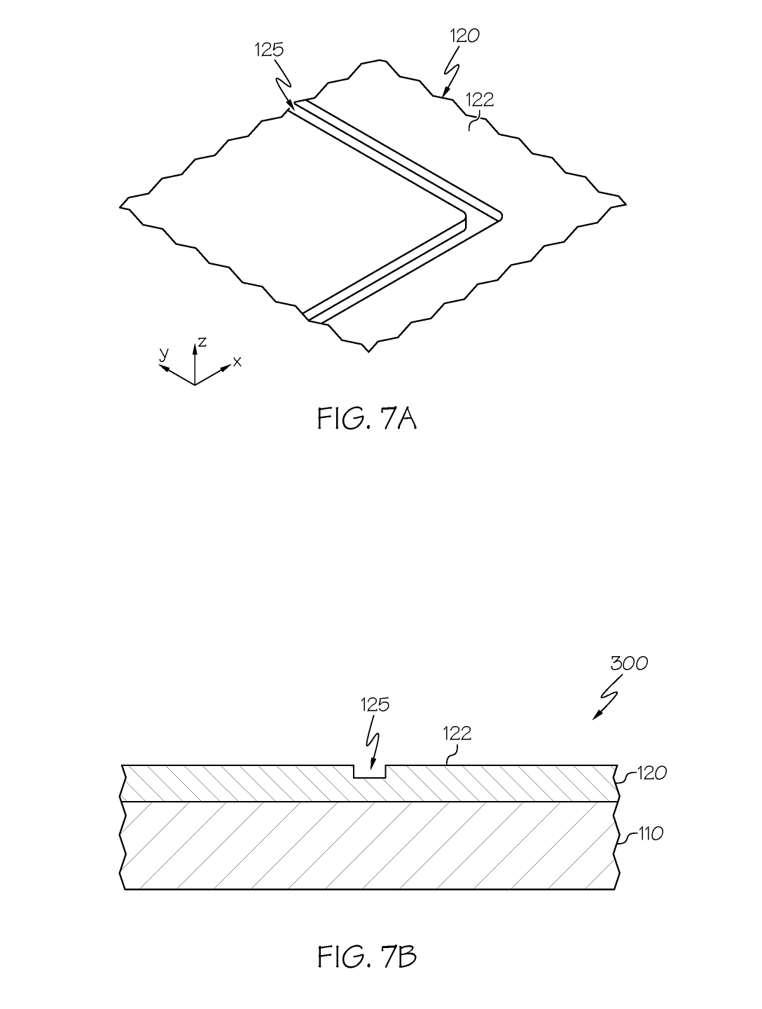

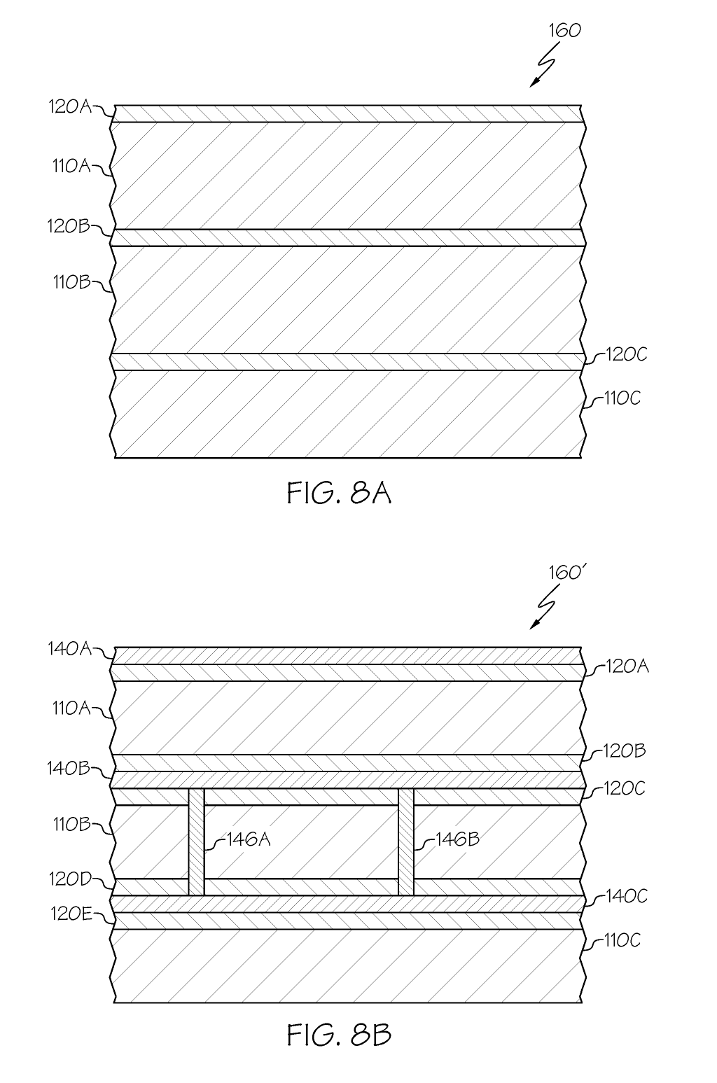

Referring now to FIG. 6A, an electrically conductive layer 142 is disposed on, under, or within the dielectric layer 120. FIG. 6A is a side view of an example glass substrate assembly 200 including an electrically conductive layer 142 disposed on a dielectric layer 120. The electrically conductive layer 142 may comprise or be configured as a plurality of electrically conductive traces and/or electrically conductive pads in accordance with a schematic for an electronic assembly. FIG. 6B is a top perspective view of the example glass substrate assembly 200 of FIG. 6A wherein the electrically conductive layer 142 includes an electrically conductive trace 145 on a surface 122 of the dielectric layer 120. The electrically conductive trace 145 may electrically couple two or more electrical components in accordance with an electric circuit, for example. The electrically conductive layer 142 may also be configured as a ground plane, for example. Accordingly, the electrically conductive layer 142 may take on any configuration. The electrically conductive layer 142 and trace 145 can be formed on top of the dielectric layer 120 and/or on top of the glass substrate 110 (e.g., between the glass substrate and the dielectric layer, or under the dielectric layer) as needed to create the required electronic circuit, transmission line, or conduction path.

The electrically conductive layer 142 may be made of any electrically conductive material capable of propagating electrical signals, such as copper, tin, silver, gold, nickel, and the like. It should be understood that other materials or material combinations may be used for the electrically conductive layer 142. The electrically conductive layer 142 may be disposed on the dielectric layer 120 by a plating process or a printing process, for example. It should be understood that any known or yet-to-be-developed process may be utilized to apply the electrically conductive layer 142 to the dielectric layer 120.

In some embodiments, a surface 122 of the dielectric layer 120 includes one or more three dimensional features. As used herein, the phrase “three dimensional feature” means a feature having a length, a width and a height. The three dimensional features may take on any size and configuration. FIGS. 7A and 7B schematically depict an example three dimensional feature configured as a channel 125 within a surface 122 of the dielectric layer 120. As an example and not a limitation, an electrically conductive trace may be disposed within the channel 125 to electrically couple electrical components. At least partially surrounding the electrically conductive trace within the channel 125 may provide electromagnetic interference shielding with respect to electric signals propagating within the electrically conductive trace, for example. Such shielding may be beneficial in high-speed communication applications, for example.

The three dimensional features may be fabricated by any known or yet-to-be-developed process. Example processes for fabricating the three dimensional features include, but are not limited to, lithographic (e.g., UV imprint lithography) and micro-replication processes.

In embodiments, multiple alternating layers of glass layers 110 and dielectric layers 120 may be arranged in a stack. Referring now to FIG. 8A, a portion of an example stack 160 comprising alternating glass layers 110A-110C and dielectric layers 120A-120C is schematically illustrated. Dielectric layer 120B is disposed between glass layers 110A and 110B, and dielectric layer 120C is disposed between glass layers 110B and 110C. Dielectric layer 120A is disposed on a top or outer surface of glass layer 110A. The individual layers may be laminated in a lamination process to form the stack 160, for example. However, the embodiments described herein are not limited to any particular method of arranging the alternating glass and dielectric layers. The multilayer stack can also include multiple dielectric layers or the same or different compositions formed on top of each other with a glass substrate disposed between them.

A stack 160 of glass and dielectric layers may be useful as a flexible printed circuit board. For example, an electrically conductive layer may be disposed within or on internal dielectric layers within the stack 160. Referring now to FIG. 8B, a portion of an example stack 160′ of glass layers 110A-110C and dielectric layers 120A-120E. In FIG. 8B, a first electrically conductive layer 140A is disposed on dielectric layer 120A, a second electrically conductive layer 140B is disposed between dielectric layer 120B and dielectric layer 120C, and a third electrically conductive layer 140C is disposed between dielectric layer 120D and dielectric layer 120E. The electrically conductive layers 140A-140C may take on any configuration, such as electrically conductive traces, ground planes, electrically conductive pads, and combinations thereof.

In embodiments, electrically conductive vias may be disposed between multiple layers to electrically couple various electrically conductive layers. FIG. 8B schematically illustrates first and second vias 146A, 146B that are disposed between dielectric layer 120C, glass layer 110B, and dielectric layer 120D to electrically couple one or more features (e.g., traces) of electrically conductive layers 140B and 140C.

The vias may be formed through various layers prior to laminating the layers into a stack. Referring to FIG. 8B, for example, dielectric layers 120C and 120D may first be applied to glass layer 110B, as described above. Vias (e.g., first and second vias 146A, 146B) may then be formed through the dielectric layers 120C, 120D and the glass layer 110B. As an example and not a limitation, the vias may be formed by a laser damage and etch process, wherein one or more laser beams pre-drill the dielectric layers 120C, 120D and glass layer 110B and a subsequent etching process expands a diameter of the vias to a desired size. An example laser drilling process is described in U.S. Pat. Appl. No. 62/208,282, which is hereby incorporated by reference in its entirety. The vias may then be filled with an electrically conductive material in a metallization process. The dielectric layers 120C, 120D and the glass layer 110B may be laminated or otherwise adhered to other layers, such as electrically conductive layers 140A and 140B and adjacent dielectric and glass layers.

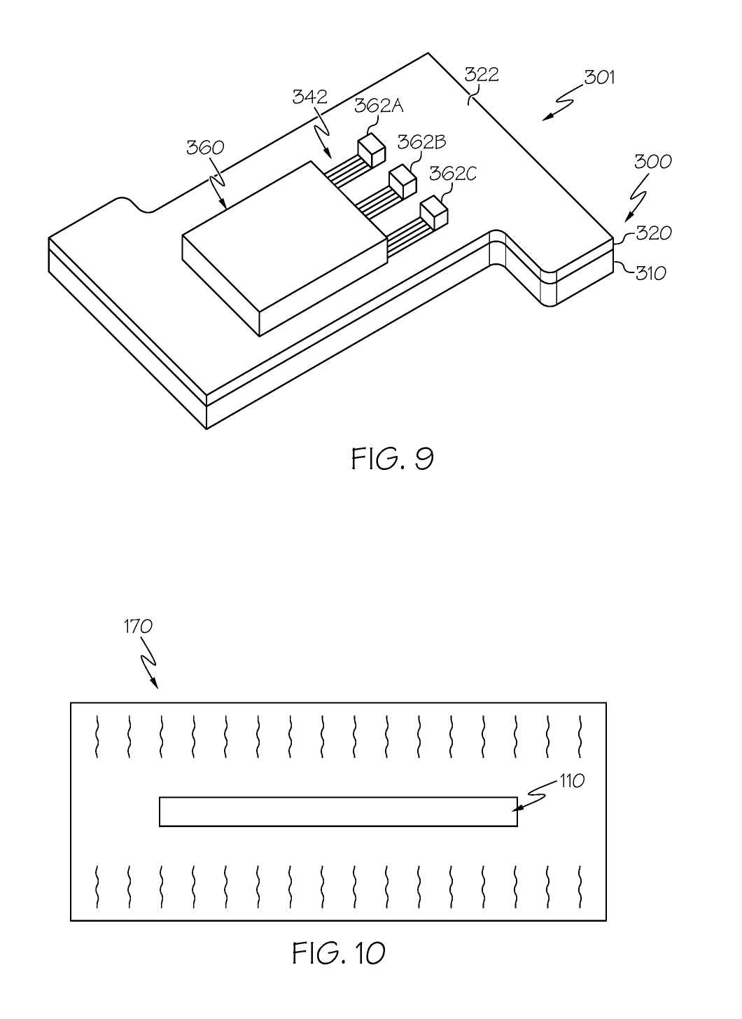

As stated above, the glass substrate assemblies described herein may be utilized as a flexible printed circuit board for an electronic assembly, such as a wireless communications electronic assembly capable of transmitting and/or receiving wireless signals. FIG. 9 schematically depicts an example electronic assembly 301. It should be understood that the illustrated electronic assembly 301 is provided for illustrative purposes only, and embodiments are not limited thereto. The electronic assembly 301 includes a substrate assembly 300 comprising at least one glass layer 310 and at least one dielectric layer 320. An integrated circuit component 360 is disposed on a surface 322 of the dielectric layer 320 (e.g., on electrically conductive pads (not shown) on or within the dielectric layer 320). Additional electrical components 362A-362C are also disposed on the surface 322 of the dielectric layer 320, and are electrically coupled to the integrated circuit component 360 by electrically conductive traces 342.

The integrated circuit component 360 may be wireless transmitter, a wireless receiver, or a wireless transceiver device. In some embodiments, the integrated circuit component 360 may be configured to transmit and/or receive wireless signals at a frequency of 10 GHz and above. The low dielectric constant and dissipation factor values of the substrate assembly 300 make the substrate assembly 300 an ideal substrate for a flexible printed circuit board.

In some embodiments, the dielectric constant value and the dissipation factor value of the glass layer may be lowered by an annealing process prior to coating the glass layer with the dielectric layer. Surprisingly, the present inventors have found that thin glass substrates subjected to an annealing process or a reforming process have lower dielectric constant and dissipation factor values in response to electromagnetic radiation having a frequency of 10 GHz than thin glass substrates not subjected to an annealing or reforming process. Experimental data shows a lowering of the dielectric constant value by up to 10% and a lowering of the dissipation factor value by more than 75% at a frequency of 10 GHz by subjecting the glass layer to the annealing process described herein. Lowering these dielectric properties of the glass layer will lower the effective dielectric properties of the substrate assemblies including a glass layer and a dielectric layer(s) described herein.

Referring now to FIG. 10, a glass layer 110 (e.g., in an individual sheet or a spool) is heated in a furnace 170 to a first temperature (e.g., a maximum temperature) that is greater than the strain point of the glass layer 110. In some embodiments, the first temperature is greater than the annealing point of the glass layer 110. Additionally, or alternatively, the first temperature is less than the softening point of the glass layer 110. As used herein, the phrase “strain point” means the temperature at which the glass layer has a viscosity of 10^{14.5} poise. As used herein, the phrase “annealing point” means the temperature at which the glass layer has a viscosity of 10¹³ poise. As used herein, the phrase “softening point” means the temperature at which the glass layer has a viscosity of 10⁷⁶ poise. The furnace 170 heats the glass layer 110 to the first temperature. In some embodiments, the temperature of the glass layer 110 is incrementally increased at a desired rate (e.g., 250° C./hour). The glass layer 110 is then held at the first temperature for a first period of time to allow the internal stresses of the glass layer 110 to relax. For example, the glass layer 110 is held within about 20%, within about 10%, within about 5%, or within about 1% of the first temperature for the first period of time. Then, the glass layer 110 is allowed to cool to a second temperature (e.g., room temperature, or about 25° C.) over a second period of time. The annealing process lowers the dielectric properties of the glass layer 110 such that the dielectric constant value is less than about 5.0 and the dissipation factor value is less than about 0.003 in response to electromagnetic radiation at a frequency of 10 GHz.

### EXAMPLES

The following examples illustrate how an annealing process lowers dielectric properties of thin glass substrates in response to electromagnetic radiation at a frequency of 10 GHz. The dielectric properties of thin glass substrates were evaluated using the split cylinder method.

### Example 1

In Example 1, two 0.1 mm Corning® EAGLE XG® glass substrates were provided. One glass substrate was used as a control and was not subjected to an annealing process, while the other glass substrate was annealed by incrementally heating the glass substrate to 700° C. at a rate of 250° C./hour. The glass substrate was maintained at 700° C. for 10 hours, and then allowed to cool to room temperature over 10 hours. The dielectric properties of both samples were evaluated at 10 GHz. The control glass substrate exhibited a dielectric constant value of about 5.14 and a dissipation factor value of about 0.0060. The annealed glass substrate exhibited a dielectric constant value of about 5.02 and a dissipation factor value of about 0.0038.

### Example 2

In Example 2, three 0.7 mm EAGLE XG® glass substrates manufactured by Corning Incorporated were provided. One glass substrate was used as a control and was not subjected to an annealing process. The second glass substrate was annealed by incrementally heating the second glass substrate to 600° C. at a rate of 250° C./hour. The second glass substrate was maintained at 600° C. for 10 hours, and then allowed to cool to room temperature over 10 hours. The third glass substrate was annealed by incrementally heating the third glass substrate to 650° C. at a rate of 250° C./hour. The third glass substrate was maintained at 650° C. for 10 hours, and then allowed to cool to room temperature over 10 hours. The dielectric properties of all three samples were evaluated at 10 GHz. The control glass substrate exhibited a dielectric constant value of about 5.21 and a dissipation factor value of about 0.0036. The second glass substrate annealed at 600° C. exhibited a dielectric constant value of about 5.18 and a dissipation factor value of about 0.0029. The third glass substrate annealed at 650° C. exhibited a dielectric constant value of about 5.18 and a dissipation factor value of about 0.0026.

### Example 3

In Example 3, two 0.7 mm Contego Glass substrates manufactured by Corning Incorporated were provided. One glass substrate was used as a control and was not subjected to an annealing process. The second glass substrate was annealed by incrementally heating the second glass substrate to 600° C. at a rate of 250° C./hour. The second glass substrate was maintained at 600° C. for 10 hours, and then allowed to cool to room temperature over 10 hours. The control glass substrate exhibited a dielectric constant value of about 4.70 and a dissipation factor value of about 0.0033. The second glass substrate annealed at 600° C. exhibited a dielectric constant value of about 4.68 and a dissipation factor value of about 0.0027.

It should now be understood that embodiments of the present disclosure provide glass substrate assemblies exhibiting desirable dielectric properties in response to high frequency wireless signals. Such glass substrate assemblies may be used as flexible printed circuit boards in electronic assemblies, such as wireless transceiver devices, for example. Particularly, the glass substrate assemblies described herein exhibit desirable dielectric constant and dissipation loss values in response to wireless signals having frequencies at 10 GHz and higher. Example glass substrates comprise a dielectric layer disposed on one or both surfaces of a thin glass layer. In some embodiments, an annealing process is used to lower the dielectric properties of the glass layer.

While exemplary embodiments have been described herein, it will be understood by those skilled in the art that various changes in form and details may be made therein without departing from the scope encompassed by the appended claims.

1. A substrate assembly comprising:
a glass layer comprising a first surface and a second surface; and
a dielectric layer disposed on at least one of the first surface or the second surface of the glass layer, the dielectric layer having a dielectric constant value of less than about 3.0 in response to electromagnetic radiation having a frequency of 10 GHz.

2. The substrate assembly of claim 1, wherein the glass layer has a thickness of less than about 300 μm.

3. The substrate assembly of claim 1, wherein the dielectric layer has a dissipation factor value of less than about 0.003 in response to electromagnetic radiation having a frequency of 10 GHz.

4. The substrate assembly of claim 1, wherein the dielectric constant value of the dielectric layer is within a range of about 2.2 to about 2.5 in response to electromagnetic radiation having a frequency of 10 GHz.

5. The substrate assembly of claim 1, wherein the glass layer has a dielectric constant value of less than about 5.0 and a dissipation factor value of less than about 0.003 in response to electromagnetic radiation having a frequency of 10 GHz.

6. The substrate assembly of claim 5, wherein the glass layer is annealed.

7. The substrate assembly of claim 5, wherein the dielectric constant value of the glass layer is within a range of about 4.7 to about 5.0, and the dissipation factor value of the glass layer is within a range of about 0.000 to about 0.003 in response to electromagnetic radiation having a frequency of 10 GHz.

8. The substrate assembly of claim 1, wherein the dielectric layer comprises a polymer.

9. The substrate assembly of claim 1, further comprising an electrically conductive layer disposed within the dielectric layer, under the dielectric layer, or on a surface of the dielectric layer.

10-11. (canceled)

12. The substrate assembly of claim 1, wherein:
a surface of the dielectric layer comprises at least one three dimensional feature;
the at least one three dimensional feature comprises a channel in the surface of the dielectric layer; and
the substrate assembly comprises an electrically conductive trace disposed within the channel.

13. The substrate assembly of claim 1, wherein a surface of the dielectric layer comprises at least one three dimensional feature, and the at least one three dimensional feature comprises a through-hole via in the dielectric layer.

14. The substrate assembly of claim 1, further comprising:
a second glass layer comprising a first surface and a second surface, the dielectric layer disposed between the second surface of the first glass layer and the first surface of the second glass layer; and
a second dielectric layer disposed on the second surface of the second glass layer.

15. The substrate assembly of claim 1, further comprising:
an electrically conductive layer disposed on a surface of the dielectric layer;
a second dielectric layer disposed on a surface of the electrically conductive layer;
a second glass layer disposed on a surface of the second dielectric layer; and
a third dielectric layer disposed on a surface of the second glass layer.

16. An electronic assembly comprising:
a glass layer comprising a first surface and a second surface;
a dielectric layer disposed on at least one of the first surface or the second surface of the glass layer, the dielectric layer having a dielectric constant value of less than about 3.0 in response to electromagnetic radiation having a frequency of 10 GHz;
a plurality of electrically conductive traces disposed within the dielectric layer, under the dielectric layer, or on a surface of the dielectric layer; and
an integrated circuit component disposed on the surface of the dielectric layer and electrically coupled to one or more electrically conductive traces of the plurality of electrically conductive traces, wherein the integrated circuit component is configured to perform at least one of transmitting or receiving wireless communication signals.

17. The electronic assembly of claim 16, wherein the glass layer has a thickness of less than about 300 μm.

18. The electronic assembly of claim 16, wherein the dielectric layer has a dissipation factor value of less than about 0.003 in response to electromagnetic radiation having a frequency of 10 GHz.

19. The electronic assembly of claim 16, wherein the dielectric constant value of the dielectric layer is within a range of about 2.2 to about 2.5 in response to electromagnetic radiation having a frequency of 10 GHz.

20. The electronic assembly of claim 16, wherein the glass layer has a dielectric constant value of less than about 5.0, and a dissipation factor value of less than about 0.003 in response to electromagnetic radiation having a frequency of 10 GHz.

21. The electronic assembly of claim 20, wherein the dielectric constant value of the glass layer is within a range of about 4.7 to about 5.0, and the dissipation factor value of the glass layer is within a range of about 0.000 to about 0.003 in response to electromagnetic radiation having a frequency of 10 GHz.

22. The electronic assembly of claim 16, wherein:
the surface of the dielectric layer comprises a plurality of channels; and
the plurality of electrically conductive traces is disposed within the plurality of channels.

23. A method of fabricating a glass substrate assembly, the method comprising:
heating a glass substrate to a first temperature that is greater than a strain point of the glass substrate and less than a softening point of the glass substrate;
maintaining the glass substrate within about 10% of the first temperature for a first period of time;
cooling the glass substrate to a second temperature over a second period of time such that, following the cooling the glass substrate, the glass substrate has a dielectric constant value of less than about 5.0 in response to electromagnetic radiation having a frequency of 10 GHz; and
applying a dielectric layer to at least one surface of the glass substrate, the dielectric layer having a dielectric constant value of less than about 2.5 in response to electromagnetic radiation having a frequency of 10 GHz.
